(19) United States
(12) Patent Application Publication
(10) Pub. No.: US 2008/0185645 A1
(43) Pub. Date: Aug. 7, 2008

(54) SEMICONDUCTOR STRUCTURE INCLUDING STEPPED SOURCE/DRAIN REGION

(75) Inventors: Zhijiong Luo, Carmel, NY (US); Huilong Zhu, Poughkeepsie, NY (US); Sunfei Fang, Lagrangeville, NY (US); Thomas W. Dyer, Pleasant Valley, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/670,100

(22) Filed: Feb. 1, 2007

(51) Int. Cl. H01L 29/78; H01L 21/336

(52) U.S. Cl. 257/347; 257/410; 438/151; 438/290; 257/E29.255; 257/E21.409

(57) ABSTRACT

A semiconductor structure includes a stepped source and drain region located in part within a semiconductor substrate that preferably has a step in a direction of a gate electrode located over a channel region that adjoins the stepped source and drain region within the semiconductor substrate. A stepped portion of the stepped source and drain region covers an extension region within the stepped source and drain region.

### BACKGROUND

1. Field of the Invention

The invention relates generally to semiconductor structures. More particularly, the invention relates to enhanced performance source and drain regions within semiconductor structures.

2. Description of the Related Art

In addition to resistors, diodes and capacitors, semiconductor circuits also commonly include transistors. Particularly common transistors that are included within semiconductor circuits are field effect transistors. Field effect transistors may be used as either or both of switching devices and signal processing devices within semiconductor circuits.

Field effect transistors typically comprise a gate electrode located upon a gate dielectric which, in turn is located over a channel region within a semiconductor substrate. The channel region separates a pair of source and drain regions within the semiconductor substrate. In addition, field effect transistors typically include spacers located adjacent and adjoining sidewalls of a gate electrode, to provide isolation between the source and drain regions and the gate electrode.

While field effect transistors are thus common in the semiconductor fabrication art, field effect transistors are nonetheless not entirely without problems. In particular, as field effect transistor structure and pitch dimensions decrease, spacer layers often cover commensurately increased portions of the source and drain regions. In addition, spacers may also provide for reductions in levels of desirable physical stress within field effect transistor structures. Unfortunately, the removal of spacer layers when fabricating field effect transistor structures to provide additional space for source and drain contact via formation and to provide desirable physical stress may in fact lead to other undesirable consequences in field effect transistor device performance or manufacturability.

Semiconductor structure dimensions are certain to continue to decrease and as a result thereof desirable are semiconductor structures and methods for fabrication thereof that provide for enhanced performance of semiconductor structures and semiconductor devices at decreased dimensions.

### SUMMARY OF THE INVENTION

The invention includes a semiconductor structure that includes a stepped source and drain region, as well as a method for fabricating the semiconductor structure. The stepped source and drain region allows for avoidance of punch-through of a comparatively thin extension region within the stepped source and drain region when forming a contact aperture into which is located a contact via that contacts the stepped source and drain region.

A semiconductor structure in accordance with the invention includes at least one field effect transistor located with and upon a semiconductor substrate. The at least one field effect transistor includes a gate electrode located over a channel region that adjoins a source and drain region located in part within the semiconductor substrate. The source and drain region includes a stepped source and drain region.

A particular method in accordance with the invention includes forming a gate dielectric and then a gate electrode over a channel region within a semiconductor substrate that adjoins a source and drain location within the semiconductor substrate. This particular method also includes forming a stepped source and drain region within the source and drain location.

Another particular method in accordance with the invention includes forming a gate dielectric and then a gate electrode over a semiconductor substrate. This other particular method also includes forming an extension region within the semiconductor substrate while using at least the gate electrode as a mask. This other particular method also includes forming an extrinsic source and drain region covering a portion of the extension region adjacent the gate electrode. Finally, this other particular method also includes forming a contact region of an intrinsic source and drain region into the semiconductor substrate while using at least the extrinsic source and drain region as a mask.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 10 show a series of schematic cross-sectional diagrams illustrating the results of progressive stages in fabricating a semiconductor structure in accordance with a particular embodiment of the invention.

FIG. 11 shows a graph of Leakage Current versus Lot Number for field effect transistor structures fabricated in accordance with the invention and not in accordance with the invention.

### DESCRIPTION OF THE PREFERRED EMBODIMENT

The invention, which includes a semiconductor structure that includes a stepped source and drain region, as well as a method for fabricating the semiconductor structure, is understood within the context of the description that follows. The description that follows is understood within the context of the drawings described above. Since the drawings are intended for illustrative purposes, the drawings are not necessarily drawn to scale.

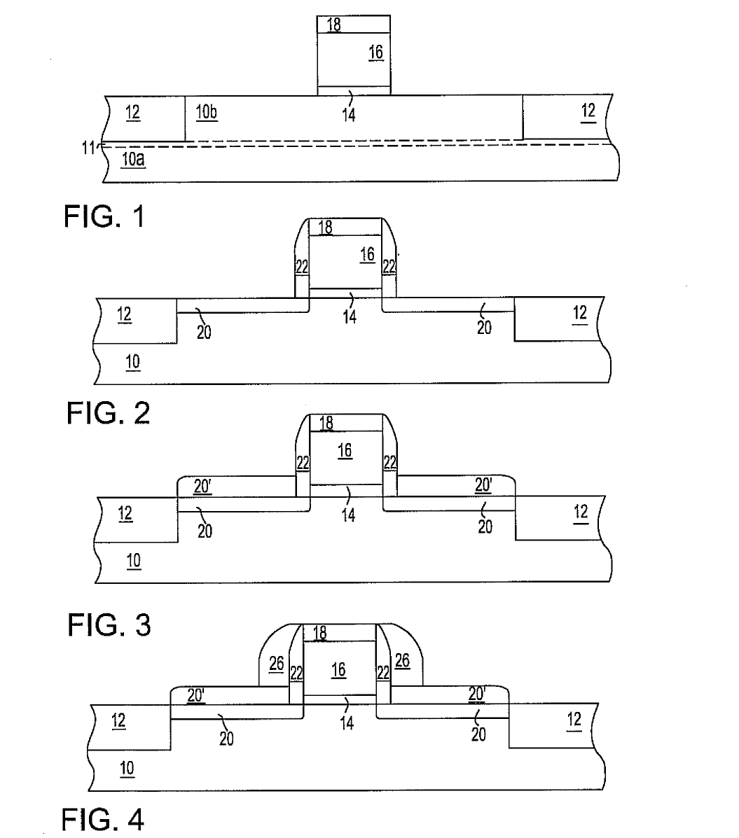

FIG. 1 to FIG. 10 show a series of schematic cross-sectional diagrams illustrating the results of progressive stages in fabricating a semiconductor structure in accordance with a particular embodiment of the invention. FIG. 1 shows a schematic cross-sectional diagram of the semiconductor structure at an early stage in fabrication thereof in accordance with this particular embodiment.

FIG. 1 shows a base semiconductor substrate 10a. An optional buried dielectric layer 11 is located upon the base semiconductor substrate 10a, and a surface semiconductor layer 10b is located upon the buried dielectric layer 11. The surface semiconductor layer 10b is bounded by a plurality of isolation regions 12. In an aggregate, the base semiconductor substrate 10a, the optional buried dielectric layer 11 and the surface semiconductor layer 10b comprise a semiconductor-on-insulator substrate.

The base semiconductor substrate 10a may comprise any of several semiconductor materials. Non-limiting examples include silicon, germanium, silicon-germanium alloy, silicon carbide, silicon-germanium carbide alloy and compound (i.e., III-V and II-VI) semiconductor materials. Non-limiting examples of compound semiconductor materials include gallium arsenide, indium arsenide and indium phosphide semiconductor materials. Typically, the base semiconductor substrate 10a has a thickness from about 1 e-6 to about 10 millimeters.

The optional buried dielectric layer 11 may comprise any of several dielectric materials. Non-limiting examples include oxides, nitrides and oxynitrides, particularly of silicon, but oxides, nitrides and oxynitrides of other elements are not excluded. The optional buried dielectric layer 11 may comprise a crystalline or a non-crystalline dielectric material, with crystalline dielectric materials being highly preferred. The optional buried dielectric layer 11 may be formed using any of several methods. Non-limiting examples include ion implantation methods, thermal or plasma oxidation or nitridation methods, chemical vapor deposition methods and physical vapor deposition methods. Typically, the optional buried dielectric layer 11 comprises an oxide of the semiconductor material from which is comprised the base semiconductor substrate 10a. Typically, the optional buried dielectric layer 11 has a thickness from about 10 to about 1e6 angstroms.

The surface semiconductor layer 10b may comprise any of the several semiconductor materials from which the base semiconductor substrate 10a may be comprised. The surface semiconductor layer 10b and the base semiconductor substrate 10a may comprise either identical or different semiconductor materials with respect to chemical composition, dopant polarity, dopant concentration and crystallographic orientation. Typically, the surface semiconductor layer 10b may have a thickness from about 10 to about 1e6 angstroms.

The isolation regions 12 may comprise any of several isolation materials that will typically comprise dielectric isolation materials. Typically, the isolation regions 12 comprise a dielectric isolation material selected from the same group of dielectric isolation materials that may be used for the optional buried dielectric layer 11. However a method used for fabricating the isolation regions 12 may be different from a method used for fabricating the optional buried dielectric layer 11. Typically, the isolation regions 12 comprise a silicon oxide or a silicon nitride dielectric material, or a composite or laminate thereof.

The semiconductor-on-insulator substrate portion of the semiconductor structure that is illustrated in FIG. 1 may be fabricated using any of several methods. Non-limiting examples include lamination methods, layer transfer methods and separation by implantation of oxygen (SIMOX) methods.

Although FIG. 1 illustrates an embodiment of the invention within the context of a semiconductor on-insulator substrate comprising the base semiconductor substrate 10a, the optional buried dielectric layer 11 and the surface semiconductor layer 10b, neither the instant embodiment nor the invention is so limited. Rather, the instant embodiment and alternative embodiments may also be practiced under certain circumstances using a bulk semiconductor substrate (that would otherwise result from absence of the optional buried dielectric layer 11 under circumstances where the base semiconductor substrate 10a and the surface semiconductor layer 10b have identical chemical composition and crystallographic orientation). For simplicity, subsequent cross-sectional diagrams within the instant embodiment are illustrated absent the optional buried dielectric layer 11, and with a single semiconductor substrate 10 rather than a base semiconductor substrate 10a and a surface semiconductor layer 10b.

Alternatively, the embodiment also contemplates use of a hybrid orientation (HOT) substrate. A hybrid orientation substrate has multiple crystallographic orientations within a single semiconductor substrate.

FIG. 1 also shows (in cross-section): (1) a gate dielectric 14 located upon the surface semiconductor layer 10a; (2) a gate electrode 16 located upon the gate dielectric 14; and (3) a capping layer 18 located upon the gate electrode 16.

Each of the foregoing layers 14, 16 and 18 may comprise materials and have dimensions that are conventional in the semiconductor fabrication art. Each of the foregoing layers 14, 16 and 18 may also be formed using methods that are conventional in the semiconductor fabrication art.

The gate dielectric 14 may comprise conventional dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the gate dielectric 14 may comprise generally higher dielectric constant dielectric materials having a dielectric constant from about 8 to at least about 100. Such higher dielectric constant dielectric materials may include, but are not limited to hafnium oxides, hafnium silicates, zirconium oxides, lanthanum oxides, titanium oxides, barium-strontium-titantates (BSTs) and lead-zirconate-titanates (PZTs). The gate dielectric 14 may be formed using any of several methods that are appropriate to its material of composition. Non limiting examples include thermal or plasma oxidation or nitridation methods, chemical vapor deposition methods (including atomic layer deposition methods) and physical vapor deposition methods. Typically, the gate dielectric 14 comprises a thermal silicon oxide dielectric material that has a thickness from about 5 to about 500 angstroms.

The gate electrode 16 may comprise materials including, but not limited to certain metals, metal alloys, metal nitrides and metal silicides, as well as laminates thereof and composites thereof. The gate electrode 16 may also comprise doped polysilicon and polysilicon-germanium alloy materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate electrode 16 comprises a doped polysilicon material that has a thickness from about 10 to about 5,000 angstroms.

The capping layer 18 comprises a capping material that in turn typically comprises a hard mask material. Dielectric hard mask materials are most common but by no means limit the instant embodiment or the invention. Non-limiting examples of hard mask materials include oxides, nitrides and oxynitrides of silicon. Oxides, nitrides and oxynitrides of other elements are not excluded. The capping material may be formed using any of several methods that are conventional in the semiconductor fabrication art. Non-limiting examples include chemical vapor deposition methods and physical vapor deposition methods. Typically, the capping layer 18 comprises a silicon nitride capping material that has a thickness from about 10 to about 1,000 angstroms.

FIG. 2 shows a plurality of first spacers 22 located adjacent and adjoining opposite sidewalls (i.e., a plurality of spacer layers in cross-sectional view but a single spacer layer in plan view) of the gate dielectric 14, gate electrode 16 and capping layer 18. FIG. 2 also shows a plurality of extension regions 20 located within the semiconductor substrate 10 and separated by the gate electrode 16, beneath which is a channel region that also separates the extension regions 20.

Within the instant embodiment, either the first spacers 22 or the extension regions 20 may be formed first, but typically the first spacers 22 will be formed first.

The first spacers 22 typically comprise a dielectric spacer material. Similarly with other dielectric structures within the instant embodiment, candidate dielectric spacer materials again include oxides, nitrides and oxynitrides of silicon. Also again, oxides, nitrides and oxynitrides of other elements are not excluded. The first spacers 22 are formed using a blanket layer deposition and anisotropic etchback method that uses an anisotropic etching plasma for etching purposes. Typically, the first spacers 22 comprise a different dielectric material than the capping layer 18. Typically, the first spacers 22 comprise a silicon oxide material when the capping layer 18 comprises a silicon nitride material.

The extension regions 20 comprise an n dopant or a p dopant appropriate to a polarity or conductivity type of a field effect transistor desired to be fabricated incident to further processing of the semiconductor structure of FIG. 2. Non-limiting examples of n dopants include arsenic dopants, phosphorus dopants, halides thereof and hydrides thereof. Non-limiting examples of p dopants include boron dopants, halides thererof and hydrides thereof. Any of the foregoing dopants may be used for forming the extension regions 20 and other doped regions described below within the instant embodiment. Less conventional alternative dopants are not excluded. As is noted above, the extension regions 20 may be formed either before or after forming the first spacers 22. Thus, the extension regions 20 are formed using an ion implant method that uses at least the gate electrode 16 as a mask. Typically, the extension regions 20 are formed to a comparatively limited depth from about 10 to about 1000 angstroms within the semiconductor substrate 10 and with a concentration from about 1e16 to about 1e22 dopant atoms per cubic centimeter within the semiconductor substrate 10.

FIG. 3 shows a plurality of extrinsic source and drain regions 20′ located upon portions of the extension regions 20 not covered by the first spacers 22. The extrinsic source and drain regions 20′ are formed using an epitaxial deposition method. Typically, the extrinsic source and drain regions 20′ are formed doped with the same polarity, but not necessarily of the same concentration or an identical dopant specie, as the extension regions 20. Appropriate doping may be provided in-situ during deposition of the extrinsic source and drain regions 20′. Alternatively, the extrinsic source and drain regions 20′ may be doped after they are formed while using an ion implantation method. Typically, the extrinsic source and drain regions 20′ have a thickness from about 10 to about 800 angstroms and a dopant concentration from about 1e16 to about 1e22 dopant atoms per cubic centimeter.

FIG. 4 shows a plurality of second spacers 26 located adjacent and adjoining exposed portions of the first spacers 22 and covering portions of the extrinsic source and drain regions 20′. Similarly with the first spacers 22, the second spacers 26 also comprise a dielectric spacer material. Also similarly with the first spacers 22, the second spacers 26 are intended as indicative of a single second spacer 26 in plan view. However, the first spacers 22 and the second spacers 26 typically comprise different dielectric spacer materials for enhanced etch specificity incident to further processing of the semiconductor structure that is illustrated in FIG. 4. Typically, the first spacers 22 comprise a silicon oxide material while the capping layer 18 and the second spacers 26 comprise a silicon nitride material. Alternative materials selections are also within the context of the embodiment and of the invention.

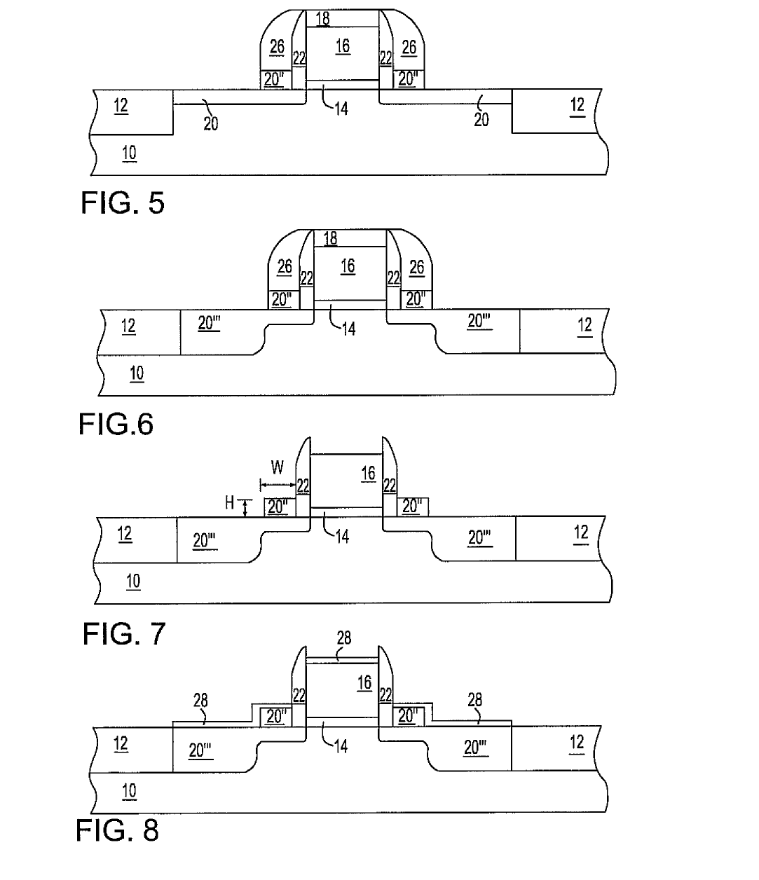

FIG. 5 shows extrinsic source and drain regions 20″ that result from etching and patterning of the extrinsic source and drain regions 20′ while using the second spacers 26 as a mask. The etching is undertaken using an anisotropic plasma etch method that uses an etchant gas composition (i.e., typically a chlorine containing etchant gas composition) that provides nominally straight sidewalls to the extrinsic source and drain regions 20″. Under certain circumstances, directional wet chemical etchant methods and materials may be used. Similarly, alternative plasma etch methods that effectively etch the extrinsic source and drain regions 20′ may also be used. While FIG. 5 illustrates the results of etching of the extrinsic source and drain regions 20′ to provide the extrinsic source and drain regions 20″ while stopping exactly upon the extension regions 20, such an exact etching of extrinsic source and drain regions 20′ to provide the extrinsic source and drain regions 20″ is not a limitation of the embodiment. Rather the extrinsic source and drain regions 20′ may be incompletely etched (i.e., leaving perhaps up to about 100 angstroms of the extrinsic source and drain regions 20′ at locations thereof uncovered by the second spacers 26) or alternatively overetched (i.e., etched to a depth of up to about 300 angstroms within the extension regions 20) when forming the extrinsic source and drain regions 20″.

FIG. 6 shows intrinsic source and drain regions 20′″ that incorporate the extension regions 20. The intrinsic source and drain regions 20′″ are formed using an ion implantation method that uses the second spacers 26, the first spacers 22 and the gate electrode 16 as a mask to form contact region portions of the intrinsic source and drain regions 20′″ that incorporate the extension regions 20. The ion implantation method also uses an implanting dopant ion of the same conductivity type and dopant polarity as used for forming the extrinsic source and drain regions 20″ and the extension regions 20. Although the chemical composition of the dopant need not be identical, the chemical composition of the dopant is typically identical. Typically, the intrinsic source and drain regions 20′″ are doped to a concentration from about 1e16 to about 1e22 dopant atoms per cubic centimeter while using the ion implantation method.

FIG. 7 shows the results of stripping the second spacers 26 and the capping layer 18 from the semiconductor structure of FIG. 6. The second spacers 26 and the capping layer 18 are stripped selectively to other features within the schematic cross-sectional diagram of FIG. 7. When the second spacers 26 and the capping layer 18 comprise a silicon nitride material, they may be selectively stripped with respect to the other features within the schematic cross-sectional diagram of FIG. 7 while using a phosphoric acid etchant at an elevated temperature. Certain plasma etch methods may also exhibit appropriate etch selectivity within the context of the instant embodiment.

As is illustrated within the schematic cross-sectional diagram of FIG. 7, the intrinsic source and drain regions 20′″ and the extrinsic source and drain regions 20″ provide stepped source and drain regions within the semiconductor structure of FIG. 7. A step height of the stepped source and drain regions increases in the direction of the gate electrode 16. The extrinsic source and drain regions 20″ provide a step height H (i.e., between adjacent plateaus that are illustrated in FIG. 7) from about 10 to about 800 angstroms (i.e., the same as the thickness of the extrinsic source and drain regions 20″) and a step width W (i.e., of an upper plateau that is illustrated in FIG. 7) from about 10 to about 500 angstroms.

As will be discussed in further detail below, the extrinsic source and drain regions 20″ cover and protect the extension region portions of the intrinsic source and drain regions 20′″ incident to further processing of the semiconductor structure of FIG. 7.

FIG. 8 shows a plurality of silicide layers 28 located upon exposed silicon containing surfaces including the intrinsic source and drain regions 20′″, the extrinsic source and drain regions 20″ and the gate electrode 16.

The silicide layers 28 may comprise any of several silicide forming metals. Non-limiting examples of candidate silicide forming metals include nickel, cobalt, titanium, tungsten, erbium, ytterbium, platinum and vanadium silicide forming metals. Nickel and cobalt silicide forming metals are particularly common. Others of the above enumerated silicide forming metals are less common. Typically, the silicide layers 28 are formed using a salicide method. The salicide method includes: (1) forming a blanket silicide forming metal layer upon the semiconductor structure of FIG. 7; (2) thermally annealing the blanket silicide forming metal layer with silicon surfaces which it contacts to selectively form the silicide layers 28 while leaving unreacted metal silicide forming metal layers on, for example, the spacers 22 and the isolation regions 12; and (3) selectively stripping unreacted portions of the silicide forming metal layers from, for example, the spacers 22 and the isolation regions 12. Typically, the silicide layers 28 comprise a nickel silicide material or a cobalt silicide material that has a thickness from about 10 to about 500 angstroms.

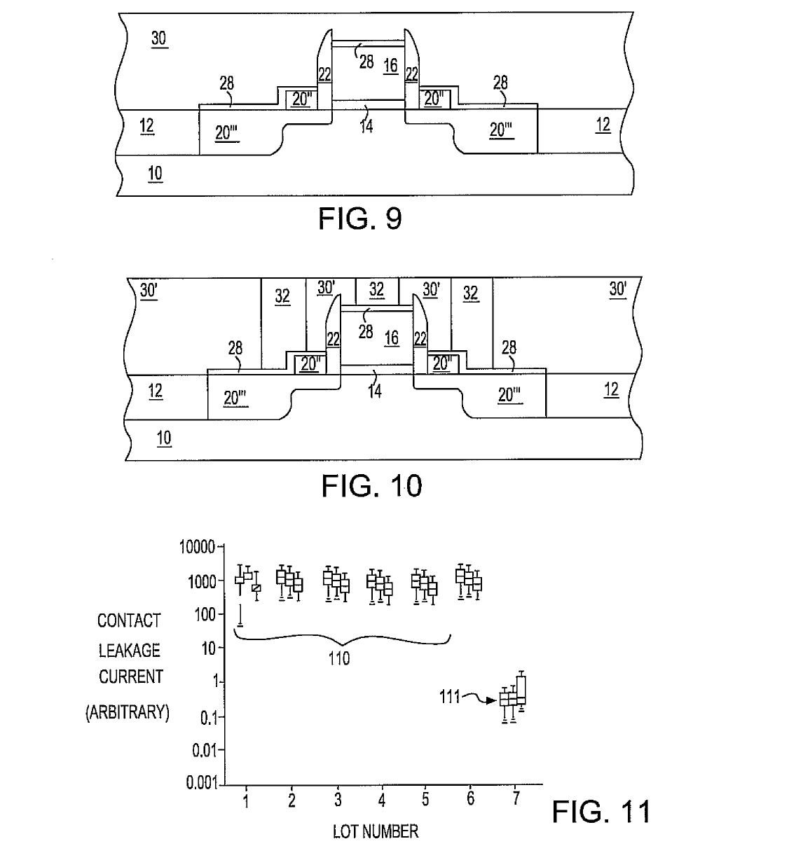

FIG. 9 shows an inter-level dielectric layer 30 located upon the semiconductor structure of FIG. 8. The inter-level dielectric layer 30 may comprise any of several inter-level dielectric materials. Generally conventional are silicon oxide, silicon nitride and silicon oxynitride inter-level dielectric materials that have a dielectric constant from about 4 to about 8, measured in vacuum. Also desirable are more contemporary inter-level dielectric materials that have a dielectric constant from about 2.5 to about 4, also measured in vacuum. Examples of these alternative inter-level dielectric materials include, but are not limited to, aerogels, hydrogels, spin-on-glass materials and spin-on-polymer materials. Also included, and also not limiting, are carbon doped materials and fluorine doped materials. The inter-level dielectric materials may be formed using methods that are appropriate to their material of composition. Non-limiting examples include chemical vapor deposition methods, physical vapor deposition methods, selective etching methods and spin-on methods. Typically, the inter-level dielectric (ILD) layer 30 comprises at least in part a doped silicate glass dielectric material that has a thickness from about 10 to about 5000 angstroms, and that is sufficiently thick to cover the semiconductor structure of FIG. 8 when forming the semiconductor structure of FIG. 9.

FIG. 10 shows a plurality of contact vias 32 located through an inter-level dielectric layer 30′ and contacting the silicide layers 28. To form the semiconductor structure that is illustrated in FIG. 10 from the semiconductor structure that is illustrated in FIG. 9, the inter-level dielectric layer 30 is first patterned to form the inter-level dielectric layer 30′. The inter-level dielectric layer 30 may be patterned to form the inter-level dielectric layer 30′ while using methods and materials that are conventional in the semiconductor fabrication art. The methods and materials will typically include photolithographic and plasma etch methods that will generally use fluorine containing etchant gas compositions for etching inter-level dielectric materials that comprise silicon containing dielectric materials. After etching the inter-level dielectric layer 30 to form the inter-level dielectric layer 30′ that includes apertures that expose the silicide layers 28, the contact vias 32 may be formed into the apertures.

The contact vias 32 may comprise any of several conductor contact materials. Non-limiting examples include certain metals, metal alloys, metal silicides and metal nitrides, as well as alloys thereof and laminates thereof. Also included are doped polysilicon and polycide conductor materials. Tungsten is a particularly common conductor contact material that may be used for forming a via. The contact vias 32 may be formed using any of several methods that are conventional in the semiconductor fabrication art. Non-limiting examples include chemical vapor deposition methods and physical vapor deposition methods. The contact vias 32 are typically formed using a blanket layer deposition and planarization method. Planarization may be effected using mechanical planarizing methods and chemical mechanical polish planarizing methods. Chemical mechanical polish planarizing methods are generally more common.

FIG. 10 shows a semiconductor structure fabricated in accordance with a preferred embodiment of the invention. The semiconductor structure includes a field effect transistor structure that includes a stepped source and drain region. The stepped source and drain region includes: (1) an intrinsic source and drain region 20′″ that incorporates an extension region: as well as (2) an extrinsic source and drain region 20″ located contacting the intrinsic source and drain region 20′″. The extrinsic source and drain region 20″ covers the extension region portion of the intrinsic source and drain region 20′″. The stepped source and drain region, and in particular the extrinsic source and drain region 20″, provides a barrier for punch-through to the extension region portion of the intrinsic source and drain region 20′″ when forming an aperture within an inter-level dielectric (ILD) layer 30′ into which is formed a contact via 32 that contacts in part a silicide layer 28 located upon the stepped source and drain region. By protecting the extension region portion of the intrinsic source and drain region 20′″ from punch-through, the semiconductor structure whose schematic cross-sectional diagram is illustrated in FIG. 10 is fabricated with reduced junction leakage currents in comparison with an otherwise analogous semiconductor structure absent the extrinsic source and drain region 20″. Similarly, by using the extrinsic source and drain region 20″ that covers only the extension region within the intrinsic source and drain region 20′″ rather than completely covering the intrinsic source and drain region 20′″, desirable mechanical stress levels within the semiconductor structure of FIG. 10 may be maintained.

FIG. 11 shows a graph of Leakage Current versus Lot Number for field effect transistor devices fabricated generally in accordance with the semiconductor structure of FIG. 10, but with and without the extrinsic source and drain regions 20″. The data points corresponding with reference numeral 110 correspond to contact leakage currents for field effect transistors that are fabricated absent extrinsic source and drain regions 20″. The data points that correspond with reference numeral 111 correspond to contact leakage currents for field effect transistors that are fabricated with extrinsic source and drain regions 20″. As is seen from the comparison of data points, field effect transistors fabricated with extrinsic source and drain regions 20″ have decreased leakage currents in comparison with field effect transistors fabricated absent extrinsic source and drain regions 20″. Reduced leakage currents are indicative of lack of punch-through of extension regions within intrinsic source and drain regions 20′″.

The preferred embodiment of the invention is illustrative of the invention rather than limiting of the invention. Revisions and modifications may be made to methods, materials, structures and dimensions of a semiconductor structure in accordance with the preferred embodiment of the invention, while still fabricating a semiconductor structure in accordance with the invention, further in accordance with the accompanying claims.

What is claimed is:

1. A semiconductor structure comprising at least one field effect transistor located within and upon a semiconductor substrate, the at least one field effect transistor including a gate electrode located over a channel region that adjoins a source and drain region located in part within the semiconductor substrate, where the source and drain region comprises a stepped source and drain region located on said semiconductor substrate.

2. The semiconductor structure of claim 1 further comprising a gate dielectric located interposed between the gate electrode and the channel region.

3. The semiconductor structure of claim 1 further comprising a first spacer interposed between the stepped source and drain region and the gate electrode.

4. The semiconductor structure of claim 1 wherein the stepped source and drain region includes an upward step in a direction of the gate electrode.

5. The semiconductor structure of claim 4 wherein the upward step has a step height between adjacent plateaus from about 10 to about 800 angstroms and a step width of an upper plateau from about 10 to about 500 angstroms.

6. The semiconductor structure of claim 1 wherein a step within the stepped source and drain region covers an extension region within the stepped source and drain region.

7. The semiconductor structure of claim 1 further comprising a silicide layer located upon the stepped source and drain region.

8. The semiconductor structure of claim 1 wherein the semiconductor substrate comprises a semiconductor-on-insulator substrate.

9. The semiconductor structure of claim 1 wherein the semiconductor substrate comprises a bulk semiconductor substrate.

10. The semiconductor structure of claim 1 wherein a step within the stepped source and drain region is raised with respect to the channel region.

11. A method for fabricating a semiconductor structure comprising:
forming a gate dielectric and then a gate electrode over a channel region within a semiconductor substrate that adjoins a source and drain location within the semiconductor substrate; and
forming a stepped source and drain region within the source and drain location.

12. The method of claim 11 wherein the forming the gate dielectric and then the gate electrode over the channel region uses a bulk semiconductor substrate.

13. The method of claim 11 wherein the forming the gate dielectric and then the gate electrode over the channel region uses a semiconductor-on-insulator substrate.

14. The method of claim 11 wherein the forming the stepped source and drain region includes forming an extrinsic source and drain region covering an extension region of an intrinsic source and drain region but not a contact region of the intrinsic source and drain region.

15. A method for fabricating a semiconductor structure comprising:
forming a gate dielectric and then a gate electrode over a semiconductor substrate;
forming an extension region within the semiconductor substrate while using at least the gate electrode as a mask;
forming an extrinsic source and drain region covering a portion of the extension region adjacent the gate electrode; and
forming a contact region of an intrinsic source and drain region into the semiconductor substrate while using at least the extrinsic source and drain region as a mask.

16. The method of claim 15 wherein the forming the extension region uses the gate electrode and a first spacer as a mask.

17. The method of claim 16 wherein the forming the extrinsic source and drain region comprises:
forming an extrinsic source and drain region covering the extension region; and
patterning the extrinsic source and drain region to form the extrinsic source and drain region that covers the portion of the extension region adjacent the gate electrode.

18. The method of claim 17 wherein the patterning the extrinsic source and drain region uses a second spacer as a mask.

19. The method of claim 15 wherein the forming the gate dielectric and then the gate electrode over the semiconductor substrate uses a semiconductor-on-insulator substrate.

20. The method of claim 15 wherein the forming the gate dielectric and then the gate electrode over the semiconductor substrate uses a bulk semiconductor substrate.
